(19) United States
(12) Patent Application Publication
(10) Pub. No.: US 2026/0291171 A1
(43) Pub. Date: Sep. 24, 2026

(54) SEMICONDUCTOR LASER WITH OPTIMIZED FACET COATINGS

(71) Applicant: NATIONAL RESEARCH COUNCIL OF CANADA, Ottawa (CA)

(72) Inventors: Daniel POITRAS, Ottawa (CA); James A. GUPTA, Gloucester (CA); Jean LAPOINTE, Ottawa (CA); Weihong JIANG, Orleans (CA); Andrew BEZINGER, Ottawa (CA); Seyed Ghasem RAZAVIPOUR, London (CA)

(21) Appl. No.: 19/476,420

(22) PCT Filed: Apr. 11, 2024
(86) PCT No.: PCT/IB2024/053553

§ 371 Date: Oct. 17, 2025

Related U.S. Application Data
(60) Provisional application No. 63/497,216, filed on Apr. 20, 2023.

(51) Int. Cl. H01S 5/028; H01S 5/065

(52) U.S. Cl. CPC H01S 5/0287; H01S 5/0654

(57) ABSTRACT

A semiconductor optical laser cavity with suppressed mode-hopping having facet optical coatings with optimized spectral properties favoring laser emission at a desired wavelength range, and suppressing mode-hopping towards undesired emission wavelengths.

### BACKGROUND OF THE INVENTION

### 1. Field of the Invention

The present invention relates generally to semiconductor lasers, and more particularly to a semiconductor laser with optimized facet coatings for suppressing mode hopping.

### 2. Description of the Related Art

Lasers usually rely on an optical cavity configuration in which resonant light travels between two mirrors and is amplified by a gain medium inside the cavity. Such optical cavities can generally sustain several resonance modes, with some of these modes being potentially amplified (if their wavelengths fall into a wavelength range where the amplification is non-zero, i.e., under the gain response curve of the lasing medium). When the laser is in operation, a mode competition can arise between the different potential emitted resonance modes where a desired emitted wavelength is usually favored by design of the laser, including the control of the gain curve position on the spectrum, and the use of diffraction gratings that help narrowing considerably the wavelength range of the favored emitted resonance modes.

The phenomenon of mode-hopping occurs when an emitted laser light suddenly jumps to a different resonance mode under the gain curve, which can be observed experimentally by an instant variation of the emitted wavelength of the laser, often accompanied by simultaneous variation of the emitted light power.

Such mode-hopping can be particularly undesirable for tunable laser applications requiring controllable and continuously variable emission wavelength at a specific resonance mode by changing a parameter of the optical cavity (i.e. refractive index), in which case mode-hopping leads to a loss of control of the wavelength. In practice, the occurrence of mode-hopping is not always well understood or easy to control, and can appear as a random event that is influenced by unforeseen imperfections in fabrication process.

The problem of mode-hopping occurs with tunable lasers that are based on external cavities, as well as tunable lasers that are based on monolithic optical cavities.

Tunable lasers based on monolithic cavities, such as tunable distributed-feedback (DFB) semiconductor lasers to produce single longitudinal mode light through the use of etched gratings that determine the emission wavelength. Such lasers inherently suffer from undesirable mode hopping between the DFB mode and nearby Fabry-Perot modes formed by the cleaved laser facets. Anti-reflection coatings are traditionally used to reduce the facet reflections and thereby suppress the Fabry-Perot modes, but do not do so selectively. Fabry-Perot modes that are not suppressed adequately can reduce the single-mode fidelity of the device.

The problem of mode hopping is particularly bad at high laser drive currents, where the tuned emitting mode may suddenly hop to an adjacent Fabry-Perot cavity mode due to heating-induced shift of the gain profile toward longer wavelengths making emission at the adjacent mode more favorable.

The problem of mode-hopping can give rise to power fluctuation of laser output, or an undesired jump of its wavelength, particularly during wavelength tuning. Many tunable lasers currently used in spectroscopy are based on external cavity configurations (e.g. Littrow configuration), and avoid mode-hopping by simultaneously varying different parameters of the configuration (i.e. simultaneously varying the cavity length and the grating position around a pivot point in the case of a Littrow configuration or changing the external cavity length and the laser temperature in the case of a vertical-cavity surface-emitting laser (VCSEL) with piezo-controlled external cavity), or by introducing a tunable band-pass filter inside the cavity (e.g. US patent publication no. US2007/0127539A1).

For monolithic lasers, most mode-hopping solutions use introduction of a phase-adjustment section with a heater (e.g. US patent publication no. US2020/0212652, July 2020); a combination of temperature control (moving the gain curve) and injection current (moving the Fabry-Perot modes), simultaneously; or a combination of cavity length control (refractive-index controlled section) and peak wavelength of a Bragg reflector (made in a refractive-index controlled section).

In the case of monolithic tunable lasers, suppressing mode-hopping with solutions involving a phase-adjustment heated section add a level of complexity to the semiconductor laser device and require an external control of the heated section. The same is true with the prior art combination of temperature control and injection current.

The following is relevant to this disclosure:

US patent publication no. US2007/0127539A1.

US patent publication no. US2020/0212652.

Pralgauskaitė, Sandra, Vilius Palenskis, Jonas Matukas, Bronius Šaulys, Vladimir Kornijčuk, and Vadimas Verdingovas. “Analysis of mode-hopping effect in Fabry-Pérot multiple-quantum well laser diodes via low frequency noise investigation.” Solid-state electronics 79 (2013): 104-110, describing the phenomenon of mode-hopping in diode lasers and its effects.

Sergey Suchalkin, Gregory Belenky, Rapidly Tunable Quantum Cascade Lasers, IEEE JOURNAL OF SELECTED TOPICS IN QUANTUM ELECTRONICS, VOL. 21, NO. 6, NOVEMBER/December 2015, 1200509, which describes a monolithic cavity having mode-hopping limitations.

Dong-Bo Wang et al., “InP-Based Surface-Emitting Distributed Feedback Lasers Operating at 2004 nm,” IEEE PHOTONICS TECHNOLOGY LETTERS, VOL. 31, NO. 21, Nov. 1, 2019, p. 1701, which describes a monolithic cavity with no mode-hopping observed, hypothetically attributed to single layer AR.

Quentin Gaimard, Meriam Triki, Tong Nguyen-Ba, Laurent Cerutti, Guilhem Boissier, Roland Teissier, Alexei Baranov, Yves Rouillard, and Aurore Vicet, “Distributed feedback GaSb based laser diodes with buried grating: a new field of single-frequency sources from 2 to 3 μm for gas sensing applications,” Opt. Express 23, 19118-19128 (20150, which describes a monolithic cavity where mode-hopping is addressed using map mode-hop vs current, temperature.

Genner A, Martin-Mateos P, Moser H, Lendl B. A Quantum Cascade Laser-Based Multi-Gas Sensor for Ambient Air Monitoring. Sensors. 2020; 20(7): 1850, which describes a monolithic cavity where mode-hopping is addressed through operation under limited current and temperature.

Pierściński, Kamil; Pierścińska, Dorota; Kuźmicz, Aleksandr; Sobczak, Grzegorz; Bugajski, Maciej; Gutowski, Piotr; Chmielewski, Krzysztof. 2020. “Coupled Cavity Mid-IR Quantum Cascade Lasers Fabricated by Dry Etching” Photonics 7, no. 3: 45, which describes the suppression of mode-hopping using a combination of temperature and injection current control.

David de Felipe Mesquida, “Tunable Lasers on a Polymer-Based Hybrid Photonic Integration Platform,” Dr. Ing. Thesis, Technischen Universität Berlin, June 2020, which describes the suppression of mode-hopping using integration of InP gain material with a polymer waveguide circuit including a phase correction section and a tunable Bragg reflector; and varying simultaneously the cavity length and the Bragg reflector peak.

The following references describe solutions to mode hopping through the use of external cavities:

M. de Labachelerie and G. Passedat, “Mode-hop suppression of Littrow grating-tuned lasers,” (eng), Applied optics, vol. 32, no. 3, pp. 269-274. 1993, which describes a mode hopping solution for external cavities with Littrow configuration.

Ojanen, S-P., J. Viheriälä, M. Cherchi, N. Zia, E. Koivusalo, P. Karioja, and M. Guina. “GaSb diode lasers tunable around 2.6 u m using silicon photonics resonators or external diffractive gratings.” Applied Physics Letters 116, no. 8 (2020): 081105, which describes GaSb based lasers with an external cavity, pivot point solution to mode hopping.

Bo Meng and Qi Jie Wang 2015 J. Opt. 17 023001, which is a review paper discussing both external cavity and monolithic cavities as well as the pivot-point solution, with no mention of any mode-hopping solution for monolithic cavities.

Vincent Lecocq et al., “Industrial integration of high coherence tunable single frequency semiconductor lasers based on VECSEL technology for scientific instrumentation in NIR and MIR,” Proc. SPIE 10087, 1008704 (2017), which describes VECSELs with external cavity and a mode hopping solution based on combining cavity length and temperature control.

### SUMMARY OF THE INVENTION

It is an aspect of the present invention to provide a semiconductor laser with optimized facet coatings for suppressing mode hopping without external cavities by controlling the dispersion of the optical feedback of the semiconductor.

In an aspect, optimized facet coatings are set forth with slopes of the reflectance spectra relative to the wavelength range covered by the desired tuned mode and the undesired mode (e.g. adjacent Fabry-Perot mode). These coatings with sloped reflectance dispersion are designed to favor the desired tuned mode in the mode competition with other adjacent undesired emission modes.

On the light emission output facet of the laser, a low reflectance coating with reflectance typically (but not limited to) between 0% and 10% can be applied, with reflectance lower at the undesired adjacent Fabry-Perot mode. On the other facet of the laser, the back facet, a higher reflectance coating with reflectance typically (but not limited to) between 80% and 95% can be applied, with reflectance lower at the undesired adjacent Fabry-Perot mode. With these two facet-coatings applied, the optical feedback at the undesired adjacent Fabry-Perot mode is much less than the optical feedback at the desired tuned emitted mode; the tuned emitted mode is thus less likely to jump to a higher undesired wavelength during tuning.

The use of facet coating to suppress mode-hoping provides a simple and passive solution to the mode-hopping problem; i.e., it does not require adding a feedback loop and external control to the laser. It is compact solution, applied directly at the laser facet. It does not require added complexity to the laser diode fabrication and operation, and involves only a modification to the laser facet coatings.

The optical coatings set forth herein can be adapted to different peak positions and shape of gain spectra vs emission wavelengths (i.e., it is contemplated for use to flatten the gain spectrum over a specific wavelength range).

The above aspects can be attained by a semiconductor optical laser cavity, comprising a front optical facet from which light is emitted; a back optical facet for reflecting light; and at least one optical coating applied to at least one of the front facet and back facet for suppression of mode-hopping, wherein the at least one optical coating is characterized by a slope of at least one of reflectance spectra and absorption spectra relative to the wavelength range covered by a desired tuned mode and an undesired tuned mode so as to favor the desired tuned mode.

According to another aspect, an optical facet coating is provided for application to at least one of a front facet and a back facet of a semiconductor optical laser cavity characterized by a slope of at least one of reflectance spectra and absorption spectra relative to the wavelength range covered by a desired tuned mode and an undesired tuned mode of the semiconductor optical laser cavity so as to favor the desired tuned mode and thereby suppress mode hopping.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1A is a schematic representation of a semiconductor optical laser cavity with front and back optical facet optical coatings, according to an embodiment.

FIG. 1B is a schematic representation of a multilayer optical facet coating of FIG. 1A with a plurality of layers applied at the interface between a facet of a semiconductor optical laser cavity and the ambient medium.

FIG. 2A is a representation of the gain in a monolithic semiconductor laser versus the emitting wavelength.

FIG. 2B is a representation of mode-hopping occurrence in a tunable semiconductor laser over different tuning parameters.

FIG. 3A shows a gain spectrum and Fabry-Perot modes favoring mode-hopping from a desired short wavelength range to longer undesired wavelengths.

FIG. 3B shows an example of a desired laser emission spectrum, according to an embodiment.

FIG. 3C shows spectral dispersion of the gain threshold gₜₕ, with a negative slope, required to suppress mode-hopping to longer wavelengths. According to an embodiment.

FIG. 3D shows a gain spectrum and Fabry-Perot modes favoring mode-hopping from a desired long wavelength range to shorter undesired wavelengths.

FIG. 3E is an example of a desired laser emission spectrum at long wavelengths, according to an embodiment.

FIG. 3F shows spectral dispersion of the gain threshold gₜₕ, with a positive slope, required to suppress mode-hopping to shorter wavelengths, according to an embodiment.

FIG. 4A and FIG. 4B show examples of optical constants dispersion curves of materials that can be used for facet optical coatings according to embodiments, where FIG. 4A shows refractive index dispersion curves and FIG. 4B shows extinction coefficient dispersion curves.

FIG. 5A, FIG. 5B, and FIG. 5C show examples of AR and HR facet coatings with positive slope TE-mode facet reflectance to reduce mode-hopping to shorter wavelengths according to embodiments, where FIG. 5A shows the AR facet mode reflectance R_{front}, FIG. 5B shows the HR facet mode reflectance R_{back}, and FIG. 5C shows the resulting −ln(R_{front}R_{back}) spectrum.

FIG. 6A, FIG. 6B and FIG. 6C show examples of AR and HR facet coatings with negative slope TE-mode facet reflectance to reduce mode-hopping to longer wavelengths according to embodiments, where FIG. 6A shows the AR facet mode reflectance R_{front}, FIG. 6B shows the HR facet mode reflectance R_{back}, and FIG. 6C shows the resulting −ln(R_{front}R_{back}) spectrum.

FIG. 7A, FIG. 7B, FIG. 7C and FIG. 7D show experimental results for the prior art and embodiments, where FIG. 7A depicts the laser emission spectra vs injected current for a prior art DFB laser with conventional facet coatings showing mode-hopping, FIG. 7B depicts the associated emission wavelength showing a discontinuous variation; FIG. 7C depicts the laser emission spectra vs injected current for a DFB laser with sloped facet coatings according to an embodiment, showing no mode-hopping and FIG. 7D shows the associated continuous variation of laser wavelength as a function of injection current.

### DETAILED DESCRIPTION OF THE PREFERRED EMBODIMENTS

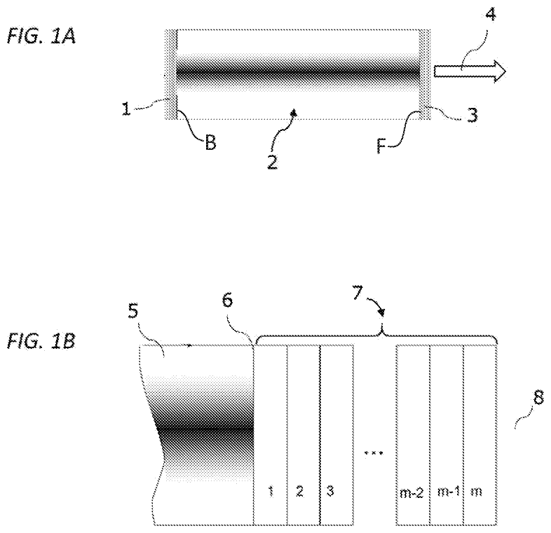

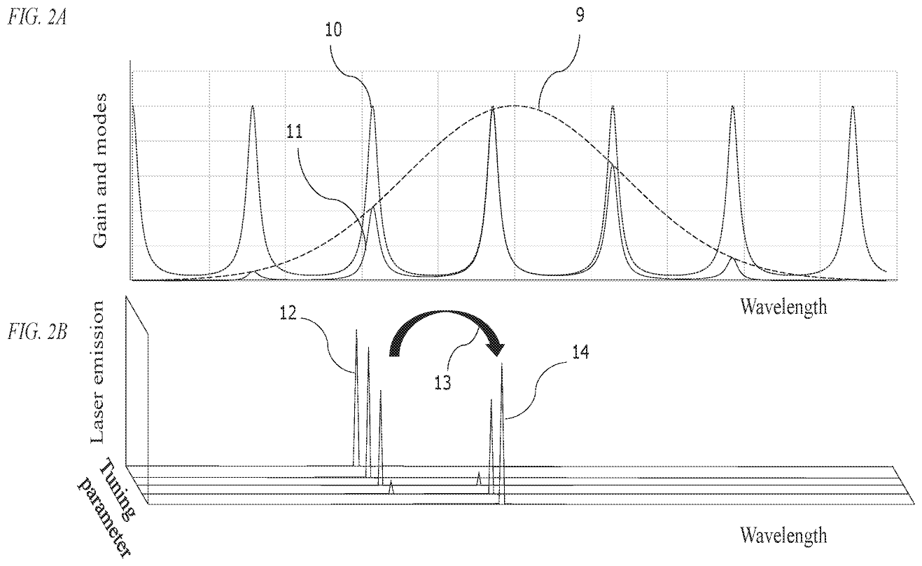

In FIG. 1A a semiconductor optical laser cavity (2) is shown, according to an embodiment, with a front (F) front optical facet from which light is emitted (4) and a back (B) optical facet for reflecting light. Optical coatings (3) and (1) are applied to the front facet (F) and back facet (B), respectively.

FIG. 1B shows a facet coating (7), according to an embodiment, having one or more layers m, applied at the interface between a facet (6), such as the front (F) and/or back (B) optical facets of a laser waveguide (5), and the ambient medium (8).

FIG. 2A shows of the gain (11) in a monolithic semiconductor laser, which is given by the active material gain curve (9) modulated by cavity Fabry-Perot modes (10), versus the emitting wavelength.

FIG. 2B is a schematic representation of mode-hopping (13) occurrence in a tunable semiconductor laser when the tuned laser wavelength (12) uncontrollably jumps to a wavelength (14) corresponding to an adjacent Fabry-Perot mode of the cavity.

In quantum electronics theory of lasers, the emitted laser modes are selected via the gain threshold gₜₕ, which is the optical gain required for lasing oscillation. The gain threshold gₜₕ, corresponds to the condition at which a mode amplification overcomes the different loss mechanisms in the laser cavity. The lowest the gₜₕ value is for a given resonance mode of the laser oscillator, the more favorable is the lasing condition for that mode.

The threshold gain can be expressed as: gₜₕ=Γₐgₐ=αᵢ−(½L) In (R_{front}×R_{back}), hereinafter Eq. 1, where R_{front} and R_{back} are the resonance mode power reflectance of the front and back surface (mirrors) delimiting the laser cavity, respectively, and αᵢ is a term including all the optical losses internal to the laser cavity, and L is the length of the cavity. The second term, Γₐgₐ, represent the optical power gain in the active medium, gₐ, multiplied by the confinement factor in that medium, Γₐ; the confinement factor depends on the light intensity field distribution in the material. The term −(½L) ln(R_{front}×R_{back}) is the mirror loss (note that for a waveguide cavity, the mode reflectance takes into account the loss of reflected light that does not recouple into the waveguide). The internal loss αᵢ can be subdivided into an absorption term αₐ, that includes all the losses that are due to absorption of light in materials inside the cavity or at its mirrors, a scattering term αₛ including all losses that are due to the scattering of light at imperfections in the waveguide or mirrors, and a radiative term αᵣ corresponding to radiative losses of light in a waveguide.

The emission wavelength can be controlled by directly controlling the gain spectrum (second term of Eq. 1) by design of the laser active material and optical cavity; for example, by moving the gain curve along the wavelength axis, and/or modulating its shape with the cavity resonance modes (i.e. Fabry-Perot modes) and modes defined by gratings inside the cavity (DBR or DFB modes).

According to an embodiment, the resonance modes behavior in the cavity is influenced so as to favor the desired emission mode by modifying the dispersion of the loss terms as a function of wavelength (right hand part of Eq. 1).

In a semiconductor optical laser cavity (2), such as the monolithic laser cavity in FIG. 1A, optical coatings can be applied on both the front facet (F) and back facet (B) of the cavity. Optical coatings (7) can be made of a single layer or can be multilayer, as shown in FIG. 1B, and can be applied at each facet (6) between the laser cavity (5) and the ambient medium (8). The back facet coating (1) usually has a high reflectance coating with a mode reflectance larger than that of the front facet (F) with or without coating, so that most of the laser light (4) emitted by the cavity (5) exits at the front facet (F).

One approach to designing facet coatings so that they can affect the loss terms and the gain threshold, as described in Eq. 1, is to choose a coating composition that results in the term −(½L) ln(R_{front}×R_{back}) in Eq. 1 being lower at the desired mode wavelength than at the adjacent Fabry-Perot wavelength. Another approach is to select a coating composition that includes at least one material having absorption that is lower at the desired mode wavelength than at the adjacent Fabry-Perot wavelength. A third approach is to include a diffusing layer that scatters less light at the desired mode wavelength than at the adjacent Fabry-Perot wavelength using, for example, the Christiansen effect. However, this specification focusses on the first two approaches, which act on R_{front} and R_{back} facet coatings spectra, and/or the absorption spectra of the coatings.

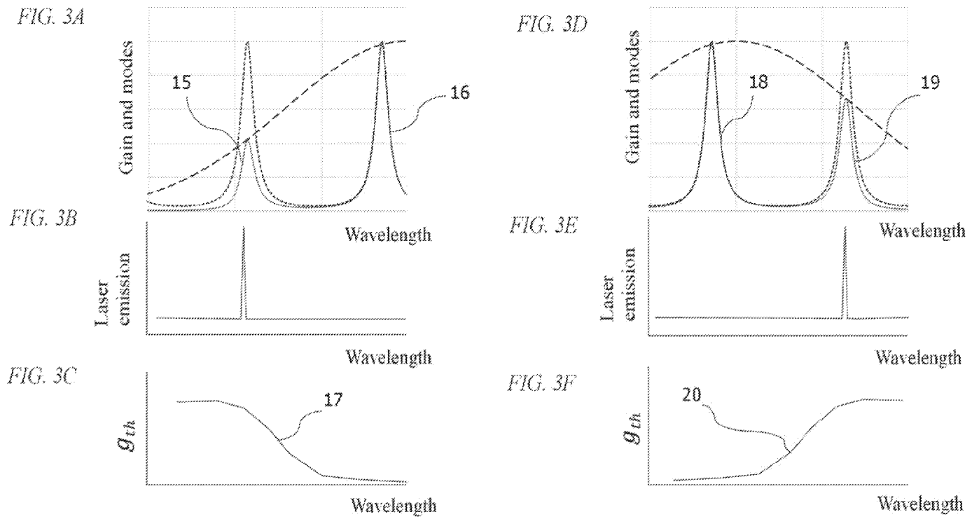

FIG. 3A and FIG. 3D show two cases of mode hopping. In FIG. 3A, the gain spectrum and Fabry-Perot modes favor mode-hopping from a short wavelength (15) to a longer wavelength (16). In FIG. 3D, the gain spectrum and Fabry-Perot modes favor mode-hopping from a longer wavelength (19) to a shorter wavelength (18). FIG. 3B and FIG. 3E show the desired emission spectra for both cases, respectively. FIG. 3C and FIG. 3F show the shape of the spectral term −(½L) ln(R_{front}×R_{back}) that is required for suppressing mode-hopping in the first and second cases, respectively. FIG. 3C shows spectral dispersion of the gain threshold gₜₕ, with a negative slope (17), required to suppress mode-hopping to longer wavelengths. FIG. 3F shows spectral dispersion of the gain threshold gₜₕ, with a positive slope (20), required to suppress mode-hopping to shorter wavelengths.

According to an embodiment, specially designed coatings can be provided having a predetermined slope in the mode reflectance spectra products R_{front}×R_{back}, corresponding to the desired spectral dispersion of the term −(½L) ln(R_{front}×R_{back}). These coatings can be applied to both the front (F) and back (B) facets, or only on one of the back (B) or front (F) facets. Moreover, the specially designed coatings can include a combination of reflectance slope and absorption in a single facet coating or both facet coatings.

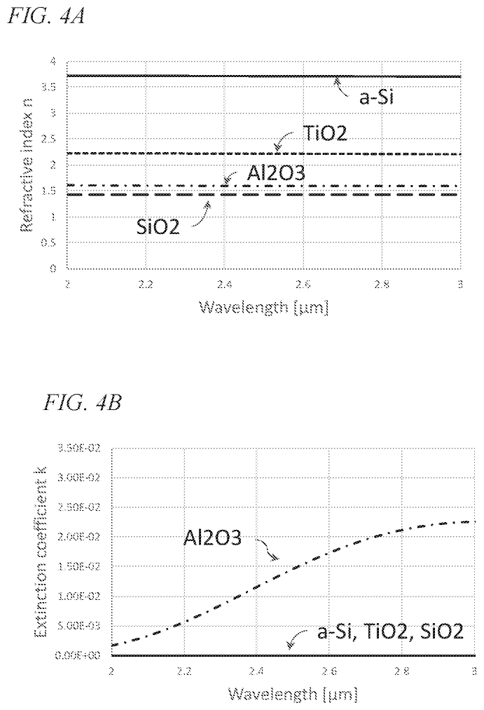

Many different materials can be used for the facet coatings, depending mainly on the wavelength range of the desired laser emission, on the fabrication techniques available and on the mechanical compatibility (adhesion, stress) with the laser cavity materials. FIG. 4A and FIG. 4B show the refractive index and extinction coefficient dispersion curves, respectively, of different materials that can be used for the coatings (1, 3) for a tunable mid-infrared laser. According to an embodiment, the coating can include silicon dioxide (SiO2), titanium dioxide (TiO2), amorphous silicon (a-Si) and aluminum oxide (Al2O3). With the exception of Al2O3, the extinction coefficient of these materials is low and does not give rise to light absorption. The Al2O3 extinction coefficient dispersion curve shows that the absorption in this material can be used in some cases to suppress mode-hopping to longer wavelengths.

Tables A and B show exemplary facet coating compositions for the front (F) and back (B) facet coatings, respectively, for suppressing mode-hopping at wavelengths shorter than the emission wavelength.

TABLE A
(Front)

| Material | (thickness [μm]) |
|---|---|
| air | |
| SiO2 | 0.005 |
| a-Si | 0.49961 |
| SiO2 | 0.21363 |
| a-Si | 0.06701 |
| TiO2 | 0.005 |
| Waveguide | |

TABLE B
(Back)

| Material | (thickness [μm]) |
|---|---|
| air | |
| TiO2 | 0.27073 |
| SiO2 | 0.52195 |
| TiO2 | 0.3383 |
| SiO2 | 0.51489 |
| TiO2 | 0.35574 |
| SiO2 | 0.45325 |
| TiO2 | 0.01 |
| Waveguide | |

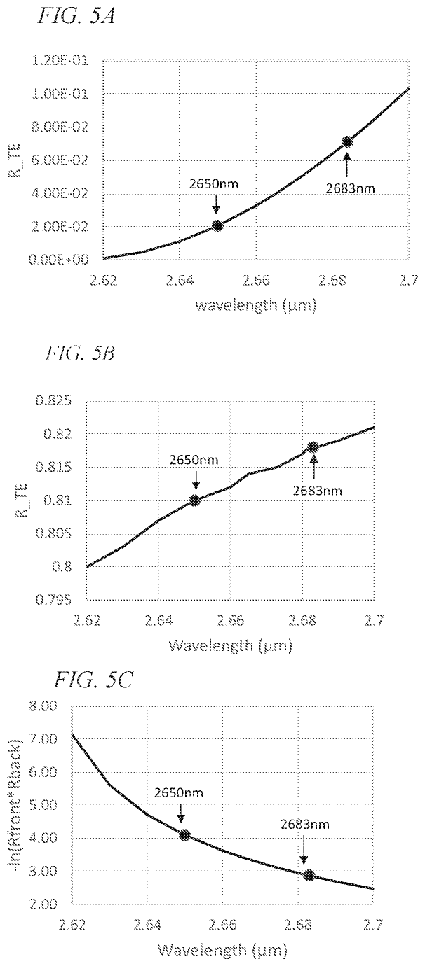

The respective sloped TE-mode reflectance spectra are shown in FIG. 5A and FIG. 5B, and the resulting gain threshold factor −(½L) ln(R_{front}×R_{back}) is shown in FIG. 5C, where FIG. 5A shows the AR facet mode reflectance R_{front}, FIG. 5B shows the HR facet mode reflectance R_{back}, and FIG. 5C shows the resulting −ln(R_{front}R_{back}).

Tables C and D show exemplary facet coating compositions for the front (F) and back (B) facet coatings, respectively, for suppressing mode-hopping at wavelengths longer than the emission wavelength.

TABLE C
(Front)

| Material | (thickness [μm]) |
|---|---|
| air | |
| SiO2 | 0.01783 |
| TiO2 | 0.30919 |
| SiO2 | 0.23316 |
| TiO2 | 0.19237 |
| Al2O3 | 0.3019 |
| Waveguide | |

TABLE D
(Back)

| Material | (thickness [μm]) |
|---|---|
| air | |
| SiO2 | 0.002 |
| a-Si | 0.18431 |
| SiO2 | 0.18602 |
| a-si | 0.09722 |
| Al2O3 | 0.46079 |
| Waveguide | |

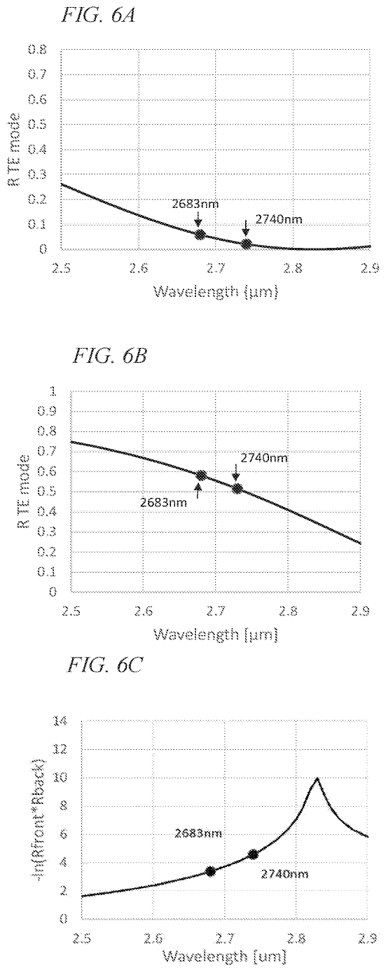

The respective negative sloped TE-mode reflectance spectra are shown in FIG. 6A and FIG. 6B, and the resulting gain threshold factor −(½L) ln(R_{front}×R_{back}) is shown in FIG. 6C, where FIG. 6A shows the AR facet mode reflectance R_{front}, FIG. 6B shows the HR facet mode reflectance R_{back}, and FIG. 6C shows the resulting −ln(R_{front}R_{back}) spectrum.

In addition, since Al2O3 is used in both the front and back facet coating designs, emitted light at longer wavelengths experience more absorption than at shorter wavelengths, thus adding to the suppression of mode-hopping at longer wavelengths.

As a demonstration of the embodiments, facet coatings in Tables A-D were fabricated on the facets of GaSb-based continuous-wave (CW) DFB tunable diode lasers in which the emission wavelength was tuned and controlled by varying the injection current. In one case, the laser emission before coating was mode-hopping at shorter wavelengths, and in another case, the laser emission before coating was mode-hopping at longer wavelengths.

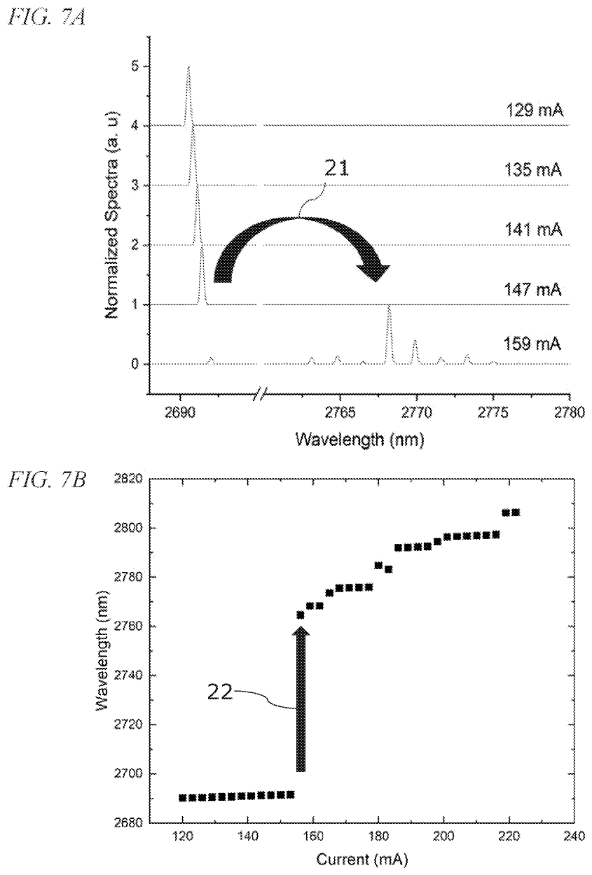

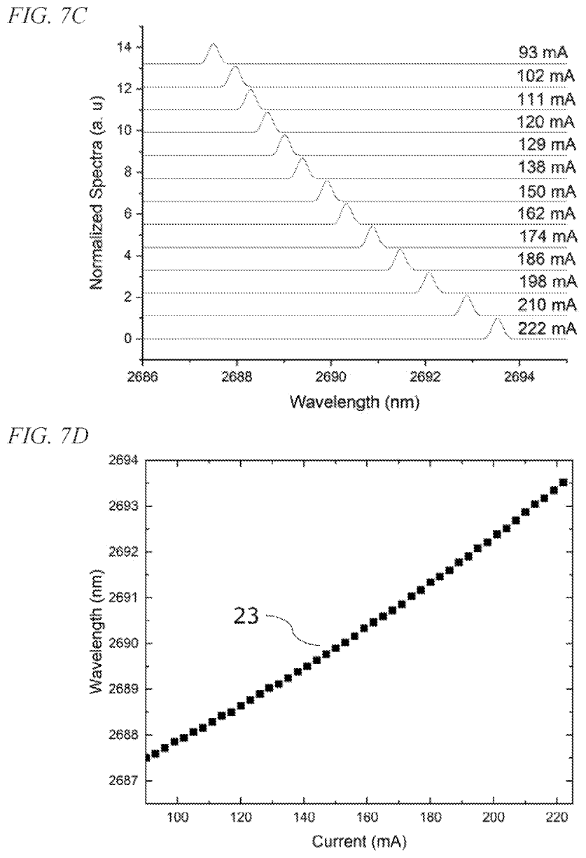

FIG. 7A is the laser emission spectra vs injected current for a DFB laser with conventional facet coatings, showing mode-hopping (21), resulting in the emission wavelength (FIG. 7B) showing a discontinuous variation (22). FIG. 7C is the laser emission spectra vs injected current for a DFB laser from the same batch, with sloped facet coatings according to Tables C and D, showing no mode-hopping and a continuous variation of laser wavelength as a function of injection current (FIG. 7D).

The embodiments set forth above do not require added complexity to the laser device, but rather a modification to the current AR and/or HR coatings applied on the front (F) and back (B) facets of the laser, respectively. In the particular case of mode-hopping in DFB monolithic semiconductor lasers between the two DFB emission modes (i.e., the modes on each side of the spectral stop-band defined by the DFB gratings), which can be relatively close to each other as compared to two adjacent Fabry-Perot modes defined by the optical cavity between the two laser facets (10 in FIG. 2A), thicker and more complex facet coatings can be used with steeper variations of their reflectance spectra, than the facet coatings of Tables A-D. In that particular case of mode-hopping between DFB modes, another solution, well-established, consists in modifying the laser design by introducing a phase-shift in the DFB gratings. However, since introducing phase-shift in the DFB gratings does not prevent mode-hopping between cavity modes, using the facet coatings as set forth herein can prevent this type of mode-hopping with phase-shifted DFB devices.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. A semiconductor optical laser cavity, comprising:
a front optical facet from which light is emitted;
a back optical facet for reflecting light; and
at least one optical coating applied to at least one of the front facet and back facet for suppression of mode-hopping, wherein the at least one optical coating is characterized by a slope of at least one of reflectance spectra and absorption spectra relative to the wavelength range covered by a desired tuned mode and an undesired tuned mode so as to favor the desired tuned mode.

2. The semiconductor optical laser cavity of claim 1, wherein the at least one optical coating comprises a plurality of layers.

3. The semiconductor optical laser cavity of claim 1, wherein the at least one optical coating comprises a single layer.

4. The semiconductor optical laser cavity of claim 1, wherein the at least one optical coating is applied to the back facet and is characterized by a high reflectance coating with a mode reflectance larger than the mode reflectance of the front facet.

5. The semiconductor optical laser cavity of claim 1, wherein the at least one optical coating is applied to the front facet and is characterized by a reflectance between 0% and 10%.

6. The semiconductor optical laser cavity of claim 5, wherein a further optical coating is applied to the back facet and is characterized by a reflectance between 80% and 95%.

7. The semiconductor optical laser cavity of claim 1, wherein the at least one optical coating is characterized by a mirror loss that is lower at the wavelength of the desired mode than at the wavelength of the undesired mode.

8. The semiconductor optical laser cavity of claim 1, wherein the at least one optical coating includes at least one material having absorption that is lower at the wavelength of the desired mode than at the wavelength of the undesired mode.

9. The semiconductor optical laser cavity of claim 2, wherein the plurality of layers includes adjacent layers between an ambient medium and the front facet of 0.005 μm of SiO2, 0.49961 μm of a-Si, 0.21363 μm of SiO2, 0.06701 μm of a-Si and 0.005 μm of TiO2 and adjacent layers between an ambient medium and the back facet of 0.27073 μm of TiO2, 0.52195 μm of SiO2, 0.03383 μm of TiO2, 0.51489 μm of SiO2, 0.35574 μm of TiO2, 0.45325 μm of SiO2 and 0.01 μm of TiO2.

10. The semiconductor optical laser cavity of claim 2, wherein the plurality of layers includes adjacent layers between an ambient medium and the front facet of 0.01783 μm of SiO2, 0.30919 μm of TiO2, 0.23316 μm of SiO2, 0.19237 μm of TiO2 and 0.3019 μm of Al2O3 and adjacent layers between an ambient medium and the back facet of 0.002 μm of SiO2, 0.18431 μm of a-Si, 0.18602 μm of SiO2, 0.09722 μm of a-Si and 0.46097 μm of Al2O3.

11. An optical facet coating for application to at least one of a front facet and a back facet of a semiconductor optical laser cavity characterized by a slope of at least one of reflectance spectra and absorption spectra relative to the wavelength range covered by a desired tuned mode and an undesired tuned mode of the semiconductor optical laser cavity so as to favor the desired tuned mode and thereby suppress mode hopping.

12. The optical facet coating of claim 11 comprising a plurality of layers.

13. The optical facet coating of claim 11 for application to the back facet and being characterized by a mode reflectance larger than a mode reflectance of the front facet.

14. The optical facet coating of claim 11 for application to the front facet and being characterized by a reflectance between 0% and 10%.

15. The optical facet coating of claim 11 for application to the back facet and being characterized by a reflectance between 80% and 95%.

16. The optical facet coating of claim 11 characterized by a mirror loss that is lower at the wavelength of the desired mode than at the wavelength of the undesired mode.

17. The optical facet coating of claim 11 including at least one material having absorption that is lower at the wavelength of the desired mode than at the wavelength of the undesired mode.

18. The optical facet coating of claim 12 wherein the plurality of layers includes adjacent layers between an ambient medium and the front facet of 0.005 μm of SiO2, 0.49961 μm of a-Si, 0.21363 μm of SiO2, 0.06701 μm of a-Si and 0.005 μm of TiO2 and adjacent layers between an ambient medium and the back facet of 0.27073 μm of TiO2, 0.52195 μm of SiO2, 0.03383 μm of TiO2, 0.51489 μm of SiO2, 0.35574 μm of TiO2, 0.45325 μm of SiO2 and 0.01 μm of TiO2.

19. The optical facet coating of claim 12 wherein the plurality of layers includes adjacent layers adjacent layers between an ambient medium and the front facet of 0.01783 μm of SiO2, 0.30919 μm of TiO2, 0.23316 μm of SiO2, 0.19237 μm of TiO2 and 0.3019 μm of Al2O3 and adjacent layers between an ambient medium and the back facet of 0.002 μm of SiO2, 0.18431 μm of a-Si, 0.18602 μm of SiO2, 0.09722 μm of a-Si and 0.46097 μm of Al2O3.
